(19) United States
(12) Patent Application Publication
(10) Pub. No.: US 2018/0145026 A1
(43) Pub. Date: May 24, 2018

(54) METHOD FOR ADJUSTING CIRCUIT CHARACTERISTICS WITH TRIMMING TECHNOLOGY IN INTEGRATED CIRCUITS

(71) Applicant: Chengdu Monolithic Power Systems Co., Ltd., Chengdu (CN)

(72) Inventors: Yuedong Chen, Chengdu (CN); Fei Xie, Chengdu (CN)

(21) Appl. No.: 15/818,616

(22) Filed: Nov. 20, 2017

(30) Foreign Application Priority Data
Nov. 22, 2016 (CN) 201611027105.1

(51) Int. Cl. H01L 23/525; G05F 1/625

(52) U.S. Cl. CPC H01L 23/5256; G05F 1/625

(57) ABSTRACT

An integrated circuit includes: a fuse; a reference resistance generator configured to receive a mode signal indicating whether the integrated circuit is working in a test mode or a normal operation mode, wherein based on the mode signal, the reference resistance generator provides a reference resistance, and wherein the reference resistance provided in the test mode is larger than the reference resistance provided in the normal operation mode; a resistance comparator coupled to the fuse and the reference resistance generator, wherein the resistance comparator compares the resistance of the fuse with the reference resistance, and generates a trimming status signal indicating whether the fuse has been trimmed; and a adjusting circuit coupled to resistance comparator and configured to adjust a circuit characteristic of the integrated circuit based on the trimming status signal.

### CROSS-REFERENCE TO RELATED APPLICATIONS

This application claims the benefit of CN application 201611027105.1, filed on Nov. 22, 2016, and incorporated herein by reference.

### TECHNICAL FIELD

The present invention generally relates to electronic circuits, and more particularly but not exclusively, to method for adjusting circuit parameters in integrated circuits (IC).

### BACKGROUND

Along with the development of IC process and design technology, requirement on circuit performance is also enhanced. However, circuit performance is always affected by non-ideal factors in semiconductor manufacture process, which mainly manifests as current mirror mismatch, resistance absolute deviation, temperature coefficient of resistors, mismatch in resistors and capacitors, transistor mismatch, offset induced by package stress, etc. These errors are random and vary from unit to unit, wafer to wafer and lot to lot, thus cannot be effectively emulated and predicted through simulation software.

To achieve high-precison analog IC in standard process, it is common to trim the IC after its manufacture to improve mismatch and temperature excursion, optimize circuit performance and increase yield. Besides, the trimming technology can also be used to adjust circuit structure and electrical parameters, so as to realize different functions on the same chip and adapt to different applications.

Prior art trimming technique generally includes laser trimming, fuse link trimming, Zener zapping and memory trimming, wherein the fuse link trimming is widely utilized because of its standard process and low cost.

### SUMMARY

Embodiments of the present invention are directed to a method for adjusting circuit characteristics in integrated circuits, comprising: comparing a resistance of a fuse with a reference resistance to detect whether the fuse has been trimmed; determining the fuse has been trimmed and adjusting the circuit characteristics of the integrated circuit if the resistance of the fuse is larger than the reference resistance; determining whether the integrated circuit is working in a test mode; and increasing the reference resistance if the integrated circuit is detected to be working in the test mode.

Embodiments of the present invention are also directed to an integrated circuit comprising: a fuse; a reference resistance generator configured to receive a mode signal indicating whether the integrated circuit is working in a test mode or a normal operation mode, wherein based on the mode signal, the reference resistance generator provides a reference resistance, and wherein the reference resistance provided in the test mode is larger than the reference resistance provided in the normal operation mode; a resistance comparator coupled to the fuse and the reference resistance generator, wherein the resistance comparator compares the resistance of the fuse with the reference resistance, and generates a trimming status signal indicating whether the fuse has been trimmed; and a adjusting circuit coupled to the resistance comparator and configured to adjust circuit characteristics of the integrated circuit based on the trimming status signal.

Embodiments of the present invention are further directed to an integrated circuit comprising: a trimming element; a reference resistance generator configured to receive a mode signal indicating whether the integrated circuit is working in a test mode or a normal operation mode, wherein based on the mode signal, the reference resistance generator provides a reference resistance, and wherein the reference resistance provided in the test mode is different from the reference resistance provided in the normal operation mode; a resistance comparator coupled to the trimming element and the reference resistance generator, wherein the resistance comparator compares the resistance of the trimming element with the reference resistance, and generates a trimming status signal indicating whether the trimming element has been trimmed; and a adjusting circuit coupled to resistance comparator and configured to adjust circuit characteristics of the integrated circuit based on the trimming status signal.

According to embodiments of the present invention, the resistance of the fuse is compared with a reference resistance to determine whether the fuse has been trimmed and whether to accordingly adjust the circuit characteristics of the IC. The reference resistance is set to a higher value in a test mode and a lower value in a normal operation mode, thus the IC delivered to customers could work as planned even if the resistance of the fuse decreases because of temperature excursion or package stress.

### BRIEF DESCRIPTION OF THE DRAWING

The present invention can be further understood with reference to the following detailed description and the appended drawings, wherein like elements are provided with like reference numerals.

FIG. 1 illustrates a prior art fuse link trimming circuit.

FIG. 2 is a block diagram of a semiconductor integrated circuit 200 in accordance with an embodiment of the present invention.

FIG. 3 illustrates a flowchart of the semiconductor integrated circuit 200 in accordance with an embodiment of the present invention.

FIG. 4 schematically illustrates a semiconductor integrated circuit 200A in accordance with an embodiment of the present invention.

FIG. 5 schematically illustrates a semiconductor integrated circuit 200B in accordance with an embodiment of the present invention.

FIG. 6 schematically illustrates a reference resistance generator 201A in accordance with an embodiment of the present invention.

FIG. 7 schematically illustrates a reference resistance generator 201B in accordance with an embodiment of the present invention.

FIG. 8 schematically illustrates a semiconductor integrated circuit 200C in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

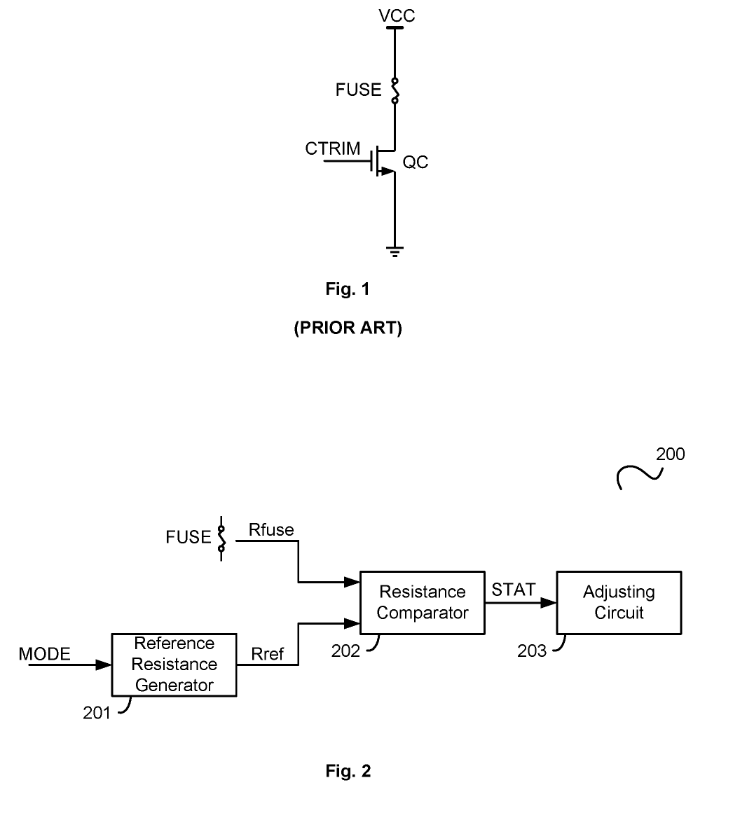

FIG. 1 illustrates a prior art fuse link trimming circuit which utilizes a high current burnout scheme. A transistor QC and a fuse are serially connected between a power supply voltage VCC and a reference ground. If the transistor QC is turned on by the trimming signal CTRIM, a large current (e.g. 150 mA) will flow through the fuse to get it heated and burnt out after a certain period (e.g. 150 mS). The resistance of the fuse is tens of ohms before burnout, but up to tens of mega ohms after. Based on this resistance, circuit characteristics (such as operation parameters or function configuration) of the IC are adjusted.

Nevertheless, if the contact between the IC and the test machine used for trimming is poor, or if the on-resistance of the transistor QC is larger than its expected value, the current flowing through the fuse might be insufficient to completely burn out the fuse, and the resistance of the fuse is probably only several kilo-ohms, or hundreds of kilo-ohms. To eliminate the adverse effect caused by this circumstance, the resistance of the fuse could be compared with a reference resistance (e.g. 20 kilo-ohms), and the circuit characteristics are adjusted only when the fuse's resistance is larger than the reference resistance.

However, the resistance of the fuse is sensitive to temperature, and might change because of the time-varying package stress. Consequently, a fuse with its resistance originally higher than the reference resistance could end up with its resistance inversely lower than the reference resistance after IC being delivered to customers. The operation of the IC would be different from its design objective, which affects the IC failure rate.

To solve this problem, the reference resistance according to embodiments of the present invention is set to a higher value in the test ahead of delivery, and a lower value in normal operation. By doing so, ICs with fuse resistance smaller than the higher value will be picked out in the test stage and rejected, to make sure ICs delivered to customers all have fuse resistance larger than the higher value. Therefore, even if the resistance of the fuse changes subsequently, it could be still larger than the lower value, which allows the circuit characteristics of the IC to be adjusted as planned.

FIG. 2 is a block diagram of a semiconductor integrated circuit 200 in accordance with an embodiment of the present invention. It includes a fuse, a reference resistance generator 201, a resistance comparator 202 and a adjusting circuit 203. The reference resistance generator 201 is configured to receive a mode signal MODE indicating whether the integrated circuit is working in a test mode or a normal operation mode, wherein based on the mode signal MODE, the reference resistance generator 201 provides a reference resistance Rref. In the normal operation mode, the reference resistance Rref provided by the reference resistance generator 201 has a first value Rref1, while in the test mode it has a second value Rref2 which is larger than Rref1. The resistance comparator 202 is coupled to the fuse and the reference resistance generator 201. It compares the resistance of the fuse with the reference resistance Rref, and generates a trimming status signal STAT indicating whether the fuse has been trimmed. The adjusting circuit 203 is coupled to the resistance comparator 202 and is configured to adjust circuit characteristics of the integrated circuit based on the trimming status signal STAT. For instance, if the resistance of the fuse is higher than the reference resistance Rref, the fuse will be deemed as trimmed. The adjusting circuit 203 could hereby set circuit parameters (e.g. a reference voltage) to a certain value, or choose a certain function, or enable or disable one or more functional circuits. Persons of ordinary skills in the art could recognize that these circuit characteristic adjusting schemes are just provided as examples, and modifications may be made without departing from the spirit and the scope of the invention.

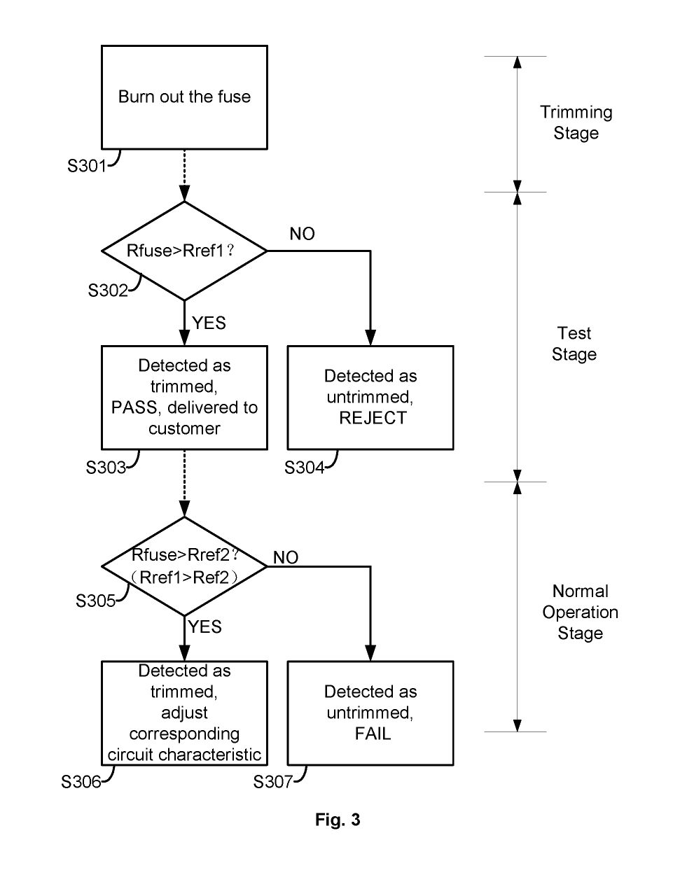

FIG. 3 illustrates a flowchart of the semiconductor integrated circuit 200 in accordance with an embodiment of the present invention.

Having substantially finished the IC fabrication, the manufacturer will conduct a series of tests to ensure the circuit characteristics of the IC meet its design objective. As illustrated in step S301, the manufacturer could burn out the fuse inside the IC to realize IC trimming. The fuse used therein is typically poly fuse or metal fuse, and the burnout could be realized by large current as shown in FIG. 1, or through laser cutting.

During the test, the reference resistance Rref compared with the resistance of the fuse is Rref1. If the resistance of the fuse is higher than Rref1, the integrated circuit will have its characteristics adjusted and reach the expected value (e.g. circuit parameters reach predetermined value, or predetermined function is adopted). Unless other problems being detected, the IC will pass the test and become ready to be delivered, as shown in step S303. Else if the resistance of the fuse is lower than Rref1, the circuit characteristics of the IC won't meet the design objective and the IC will be picked out and rejected, as shown in step S304.

After being delivered to customers and entering into normal operation, as described in step S305, the resistance comparator 202 compares the resistance of the fuse with Rref2. If the resistance of the fuse is higher than Rref2, the adjusting circuit 203 will adjust the circuit characteristics of the IC into predetermined value, as shown in step S306. Otherwise, the fuse will be deemed as untrimmed and the adjusting circuit 203 would not adjust the circuit characteristics. In this situation, as shown in step S307, the operation of the IC will not match the design objective and the IC fails.

The reference resistance value Rref1 and Rref2 could be selected based on practical applications. Assuming Rref2 is fixed, then the larger the difference between Rref1 and Rref2, the more the ICs rejected in the test stage and the lower the yield. In contrast, the lower the difference between Rref1 and Rref2, the easier for the fuse of the resistance changes from being higher than Rref1 into lower than Rref2 because of temperature or package stress, and consequently the higher the failure rate after delivered to customers. In one embodiment, Rref1 is 100 kilo-ohms, and Rref2 is 20 kilo-ohms.

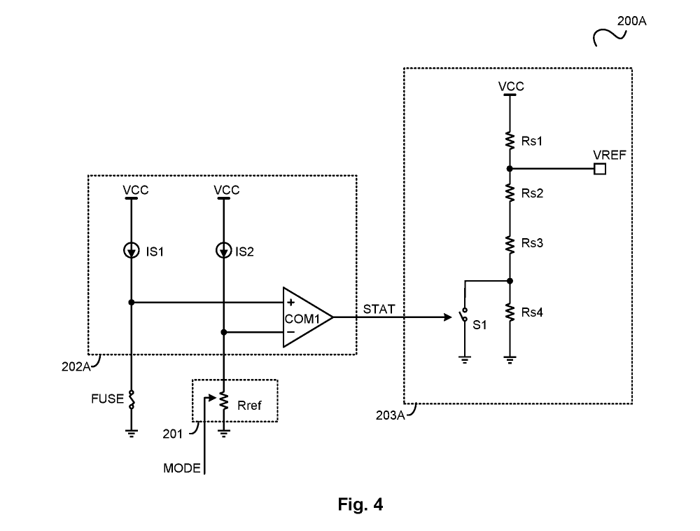

FIG. 4 schematically illustrates a semiconductor integrated circuit 200A in accordance with an embodiment of the present invention, wherein the reference resistance generator 201 is illustrated as a variable resistor controlled by the mode signal MODE. The resistance comparator 202A includes a comparator COM1 and current source IS1-IS2. The comparator COM1 has a non-inverting input terminal, an inverting input terminal and an output terminal, wherein the fuse is coupled between the non-inverting input terminal and a reference ground, the reference resistance generator 201 is coupled between the inverting input terminal and the reference ground, and the output terminal of the comparator COM1 is configured to provide the trimming status signal STAT. The current source IS1 and IS2 each has a first terminal and a second terminal, wherein the first terminals are both coupled to a power supply voltage VCC, and the second terminals are respectively coupled to the non-inverting input terminal and inverting input terminal of the comparator COM1. In the embodiment shown in FIG. 4, the adjusting circuit 203A contains a transistor S1 and resistors Rs1-Rs4, and is configured to adjust a reference voltage VREF in accordance with the trimming status signal STAT.

Referring to FIG. 4, if untrimmed, the resistance of the fuse will be lower than the reference resistance Rref provided by the reference resistance generator 201, thus the voltage at the non-inverting input terminal of the comparator COM1 will be smaller than that at the inverting input terminal, and the trimming status signal STAT will be logical low. The transistor S1 in the adjusting circuit 203A will turn on, and the reference voltage VREF could be expressed as:

$$VREF = VCC * \frac{Rs 2 + Rs 3}{Rs 1 + Rs 2 + Rs 3}$$

If trimmed, the resistance of the fuse will be higher than the reference resistance Rref, thus the voltage at the non-inverting input terminal of the comparator COM1 will be bigger than that at the inverting input terminal, and the trimming status signal STAT will be logical high. The transistor S1 in the adjusting circuit 203A will turn off, and the reference voltage VREF could be expressed as:

$$VREF = VCC * \frac{Rs 2 + Rs 3 + Rs 4}{Rs 1 + Rs 2 + Rs 3 + Rs 4}$$

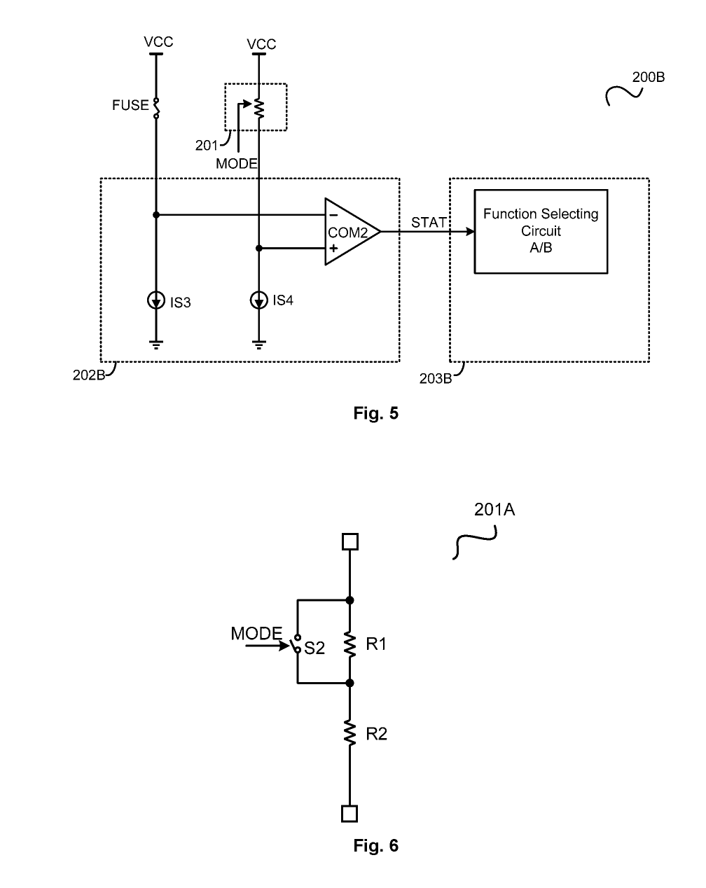

FIG. 5 schematically illustrates a semiconductor integrated circuit 200B in accordance with an embodiment of the present invention, wherein the resistance comparator 202B contains a comparator COM2 and current source IS3-IS4. The comparator COM2 has a non-inverting input terminal, an inverting input terminal and an output terminal, wherein the reference resistance generator 201 is coupled between the power supply voltage VCC and the non-inverting input terminal, the fuse is coupled between the power supply voltage VCC and the inverting input terminal, and the output terminal of the comparator COM2 is configured to provide the trimming status signal STAT. The current source IS3 and IS4 each has a first terminal and a second terminal, wherein the first terminals are respectively coupled to the inverting input terminal and non-inverting input terminal of the comparator COM2, and the second terminals are coupled to the reference ground. Difference from the embodiment shown in FIG. 4, the adjusting circuit 203B contains a function selecting circuit which is capable of selectively performing either a first function A or a second function B based on the trimming status signal STAT.

Referring to FIG. 5, if untrimmed, the resistance of the fuse will be lower than the reference resistance Rref, thus the voltage at the non-inverting input terminal of the comparator COM2 will be smaller than that at the inverting input terminal. The trimming status signal STAT will be logical low, and the function selecting circuit will accordingly perform function A.

If trimmed, the resistance of the fuse will be higher than the reference resistance Rref, thus the voltage at the non-inverting input terminal of the comparator COM2 will be ser than that at the inverting input terminal. The trimming status signal STAT will be logical high, and the function selecting circuit will accordingly perform function B.

FIG. 6 schematically illustrates a reference resistance generator 201A in accordance with an embodiment of the present invention. The reference resistance generator 201A includes resistors R1, R2 and a transistor S2 controlled by the mode signal MODE. When the IC works in the test mode, the mode signal MODE turns off the transistor S2, and the reference resistance provided by the reference resistance generator 201A could be expressed as:

Rref1=R1+R2

When the IC works in the normal operation mode, the mode signal MODE turns on the transistor S2 to short the resistor R1, and the reference resistance provided by the reference resistance generator 201A could be expressed as:

Rref2=R2

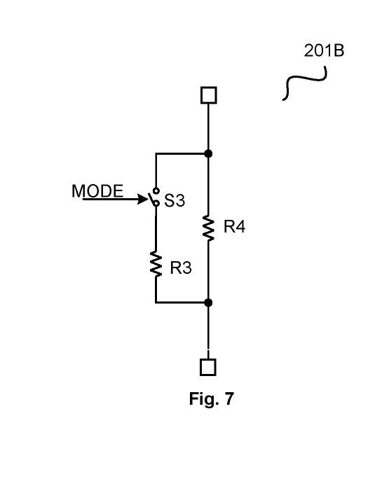

FIG. 7 schematically illustrates a reference resistance generator 201B in accordance with an embodiment of the present invention. The reference resistance generator 201B includes resistors R3, R4 and a transistor S3 controlled by the mode signal MODE. When the IC works in the test mode, the mode signal MODE turns off the transistor S3, and the reference resistance provided by the reference resistance generator 201B could be expressed as:

Rref1=R4

When the IC works in the normal operation mode, the mode signal MODE turns on the transistor S3, and the reference resistance provided by the reference resistance generator 201B could be expressed as:

$$Rref 2 = \frac{R 3 \times R 4}{R 3 + R 4}$$

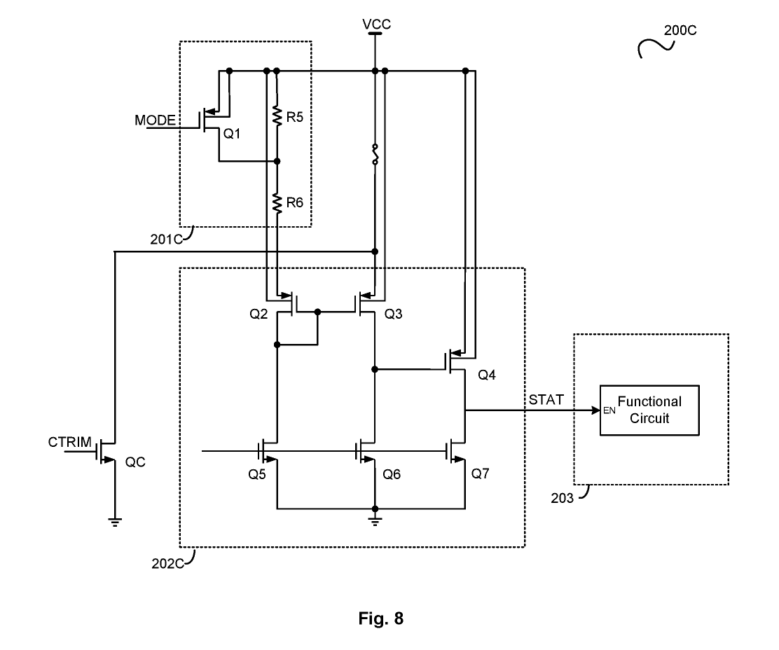

FIG. 8 schematically illustrates a semiconductor integrated circuit 200C in accordance with an embodiment of the present invention. It comprises a reference resistance generator 201C, a resistance comparator 202C, a adjusting circuit 203C and a transistor QC coupled between the fuse and the reference ground. The transistor QC is controlled by a trimming signal CTRIM and is utilized to generate a large current for burning out the fuse. As shown in FIG. 8, the reference resistance generator 201C is similar to the circuit shown in FIG. 6, and includes resistors R5, R6 and a transistor Q1. The resistor comparator 202C is coupled to the fuse and the reference resistance generator 201C, and contains transistors Q2-Q7. The adjusting circuit 203C includes a functional circuit. The trimming status signal STAT generated by the resistance comparator 202C is provided to the enable terminal EN of the functional circuit to enable or disable the functional circuit. This functional circuit could be any device, cell, circuit or block which is capable of performing certain function.

Although the embodiments described above all focus on fuse link trimming, people with ordinary skill in the art could recognize, however, that the present invention is also applicable to other trimming elements, such as film resistor, Zener diode and etc., with appropriate adjustment of the value of Rref1 and Rref2 and the relationship in between.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A method for adjusting circuit characteristics in an integrated circuit, comprising:
comparing a resistance of a fuse with a reference resistance to detect whether the fuse has been trimmed;
determining the fuse has been trimmed and adjusting a circuit characteristic of the integrated circuit if the resistance of the fuse is larger than the reference resistance;
determining whether the integrated circuit is working in a test mode; and
increasing the reference resistance if the integrated circuit is detected to be working in the test mode.

2. The adjusting method of claim 1, wherein adjusting the circuit characteristic of the integrated circuit includes correcting operation parameters of the integrated circuit.

3. The adjusting method of claim 1, wherein adjusting the circuit characteristic of the integrated circuit includes getting a function selecting circuit inside the integrated circuit to perform a first function rather than a second function different from the first function.

4. The adjusting method of claim 1, wherein adjusting the circuit characteristic of the integrated circuit includes enabling or disabling a functional circuit performing a certain function inside the integrated circuit.

5. The adjusting method of claim 1, wherein the step of comparing the resistance of the fuse with the reference resistance is realized by comparing the voltage across the fuse with the voltage across a reference resistance generator.

6. An integrated circuit comprising:
a fuse;
a reference resistance generator configured to receive a mode signal indicating whether the integrated circuit is working in a test mode or a normal operation mode, wherein based on the mode signal, the reference resistance generator provides a reference resistance, and wherein the reference resistance provided in the test mode is larger than the reference resistance provided in the normal operation mode;
a resistance comparator coupled to the fuse and the reference resistance generator, wherein the resistance comparator compares the resistance of the fuse with the reference resistance, and generates a trimming status signal indicating whether the fuse has been trimmed; and
a adjusting circuit coupled to the resistance comparator and configured to adjust a circuit characteristic of the integrated circuit based on the trimming status signal.

7. The integrated circuit of claim 6, wherein based on the trimming status signal, the adjusting circuit corrects operation parameters of the integrated circuit.

8. The integrated circuit of claim 6, wherein the adjusting circuit includes a function selecting circuit, wherein based on the trimming status signal, the function selecting circuit selectively performs a first function or a second function different from the first function.

9. The integrated circuit of claim 6, wherein the adjusting circuit includes a functional circuit, wherein the functional circuit is enabled or disabled based on the trimming status signal.

10. The integrated circuit of claim 6, wherein the resistance comparator comprises:
a first comparator having a first input terminal, a second input terminal and an output terminal, wherein the fuse is coupled between the first input terminal of the first comparator and a reference ground, the reference resistance generator is coupled between the second input terminal of the first comparator and the reference ground, and the output terminal of the first comparator is configured to provide the trimming status signal;
a first current source having a first terminal and a second terminal, wherein the first terminal is coupled to a power supply voltage, the second terminal is coupled to the first input terminal of the first comparator; and
a second current source having a first terminal and a second terminal, wherein the first terminal is coupled to the power supply voltage, the second terminal is coupled to the second input terminal of the first comparator.

11. The integrated circuit of claim 6, wherein the resistance comparator comprises
a second comparator having a first input terminal, a second input terminal and an output terminal, wherein the reference resistance generator is coupled between a power supply voltage and the first input terminal of the second comparator, the fuse is coupled between the power supply voltage and the second input terminal of the second comparator, and the output terminal of the second comparator is configured to provide the trimming status signal;
a third current source having a first terminal and a second terminal, wherein the first terminal is coupled to the second input terminal of the second comparator, the second terminal is coupled to a reference ground; and
a fourth current source having a first terminal and a second terminal, wherein the first terminal is coupled to the first input terminal of the second comparator, the second terminal is coupled to the reference ground.

12. The integrated circuit of claim 6, wherein the reference resistance generator includes:
a first resistor;
a second resistor serially coupled to the first resistor; and
a first transistor coupled to the first resistor in parallel and controlled by the mode signal.

13. The integrated circuit of claim 6, further comprising a second transistor coupled between the fuse and a reference ground.

14. An integrated circuit comprising:
a trimming element;
a reference resistance generator configured to receive a mode signal indicating whether the integrated circuit is working in a test mode or a normal operation mode, wherein based on the mode signal, the reference resistance generator provides a reference resistance, and wherein the reference resistance provided in the test mode is different from the reference resistance provided in the normal operation mode;
a resistance comparator coupled to the trimming element and the reference resistance generator, wherein the resistance comparator compares the resistance of the trimming element with the reference resistance, and generates a trimming status signal indicating whether the trimming element has been trimmed; and
a adjusting circuit coupled to resistance comparator and configured to adjust a circuit characteristic of the integrated circuit based on the trimming status signal.

15. The integrated circuit of claim 14, wherein based on the trimming status signal, the adjusting circuit corrects operation parameters of the integrated circuit.

16. The integrated circuit of claim 14, wherein the adjusting circuit includes a function selecting circuit, wherein based on the trimming status signal, the function selecting circuit selectively performs a first function rather than a second function different from the first function.

17. The integrated circuit of claim 14, wherein the adjusting circuit includes a functional circuit, wherein the functional circuit is enabled or disabled based on the trimming status signal.
